(19) United States
(12) Patent Application Publication
(10) Pub. No.: US 2007/0126355 A1
(43) Pub. Date: Jun. 7, 2007

(54) Dual emission display

(75) Inventors: Chun-Yi Chiu, Taoyuan City (TW); Min-Chieh Hu, Tainan Hsien (TW)

Correspondence Address: BIRCH STEWART KOLASCH & BIRCH, PO BOX 747, FALLS CHURCH, VA, 22040-0747, US

(73) Assignee: AU Optronics Corp.

(21) Appl. No.: 11/448,816

(22) Filed: Jun. 8, 2006

(30) Foreign Application Priority Data
Dec. 2, 2005 (TW) 94142592

(51) Int. Cl. H05B 33/04; H01L 51/52

(52) U.S. Cl. 313/512; 313/503

(57) ABSTRACT

A dual emission display includes a substrate, a first light emitter, a second light emitter and a cap. The two light emitters are disposed on the substrate. The first light emitter has a first light-emitting direction. The second light emitter is adjacent to the first light emitter, and has a second light-emitting direction. The cap is located on the first emitter and the second emitter, and is separated from one of the first emitter and the second emitter by a distance ranging from about 1 μm to 100 μm.

This application claims the benefit of Taiwan Patent Application Serial No. 094142592, filed Dec. 2, 2005, the subject matter of which is incorporated herein by reference.

### BACKGROUND OF THE INVENTION

(1) Field of the Invention

The present invention relates to dual emission display, and more particularly, to a dual organic electroluminescent display capable of protecting its light emitters from damaging by external forces.

(2) Description of the Prior Art

As the electric products are getting more and more various, they emphasize the structure of two display screens. For example, a mobile phone having a dual emission display can display a main function menu at one side, and display time at the other side. Typically, the dual emission display includes two adhered single-side panels, such as a liquid crystal panel adhered to an organic electro-luminescent panel, two adhered liquid crystal panels, or two adhered organic electro-luminescent panels.

FIG. 1 shows a dual emission display according to the prior art. The dual emission display 10 includes a first display panel 11 and a second display panel 12. The first display panel 11 has a transparent substrate 111, a first electrode 112, an emission layer 113, a second electrode 114 and a package lid 115. The first electrode 112 is formed on the transparent substrate 111. The emission layer 113 is disposed between the first electrode 112 and the second electrode 114. The package lid 115 is adhered on the transparent panel 111 and covers on the second electrode 114.

The second display panel 12 has a transparent substrate 121, a third electrode 122, an emission layer 123, a forth electrode 124 and a package lid 125. The third electrode 122 is formed on the transparent panel 121. The emission layer 123 is disposed between the third electrode 122 and the forth electrode 124. The package lid 125 is adhered on the transparent substrate 121. The package lid 115 is adhered to the package lid 125 to construct the dual emission display 10.

As stated above, the conventional dual emission display 10 has two package lids 115 and 125, and two transparent substrates 111 and 121. Therefore, it becomes larger, thicker, and heavier, so as not to meet the requirement of weight, thickness and size. For reducing thickness, the gap between the package lip and the transparent substrate should be reduced. The disadvantages is that, when the package lid is pressed to bend or to press the particles generated from the fabricating process, the elements mounted on the substrate is damaged easily by the bended package lid or the pressed particles.

Besides, the two display panels 11 and 12 are respectively manufactured in two different processes. Therefore, the manufacture of the conventional dual emission display 10 is complicated and time-consuming. Another drawback is that the two display panels 11 and 12 need to be driven independently. Thus, the cost is increased because no components such as chips or flexible printed circuits (FPCs) are saved.

The typical dual emission display is thicker and is fabricated by more complicated process due to using more components such as package lids and substrates. The elements mounts on the substrate is damaged easily by the particles generating from the fabricating process. Therefore, it is desirable to provide a new dual emission display capable of avoiding above disadvantages associated with typical dual emission displays.

### SUMMARY OF THE INVENTION

The object of the present invention is to provide a thinner dual emission display which is adapted to simpler fabricating process and capable of preventing particles from damaging the light emitter on the substrate.

According to the present invention, the dual emission display includes a substrate, a first light emitter, a second light emitter and a cap. The two light emitters are disposed on the substrate. The first light emitter has a first light-emitting direction. The second light emitter is next to the first light emitter, and has a second light-emitting direction. The cap is located on the first emitter and the second emitter, and is separated from one of the first emitter and the second emitter by a distance ranging from about 1 μm to 100 μm.

The distance from the cap to the two emitters can be adjusted according to the particle size. In a preferred embodiment, the first light emitter may emit upward, and the second light emitter may emit downward. A spacing layer is sandwiched between the first and second emitters. A supporting layer is interposed between the cap and the non-upward emitting elements such as the spacing layer, or the second light emitter. Therefore, it is avoidable to press the cap to result in deformation. Further, elements disposed on the substrate are protected.

### BRIEF DESCRIPTION OF THE DRAWINGS

The present invention will now be specified with reference to its preferred embodiment illustrated in the drawings, in which

FIG. 1 is an dual emission display according to the prior art;

FIG. 2 is an first embodiment of the dual emission display according to the present invention;

FIG. 3A shows the first type layout diagram of the light emitter according to the first embodiment of the present invention;

FIG. 3B shows the second type layout diagram of the light emitter according to the first embodiment of the present invention.;

FIG. 4 is the second embodiment of the dual emission display according to the present invention; and

FIG. 5 is the third embodiment of the dual emission display according to the present invention.

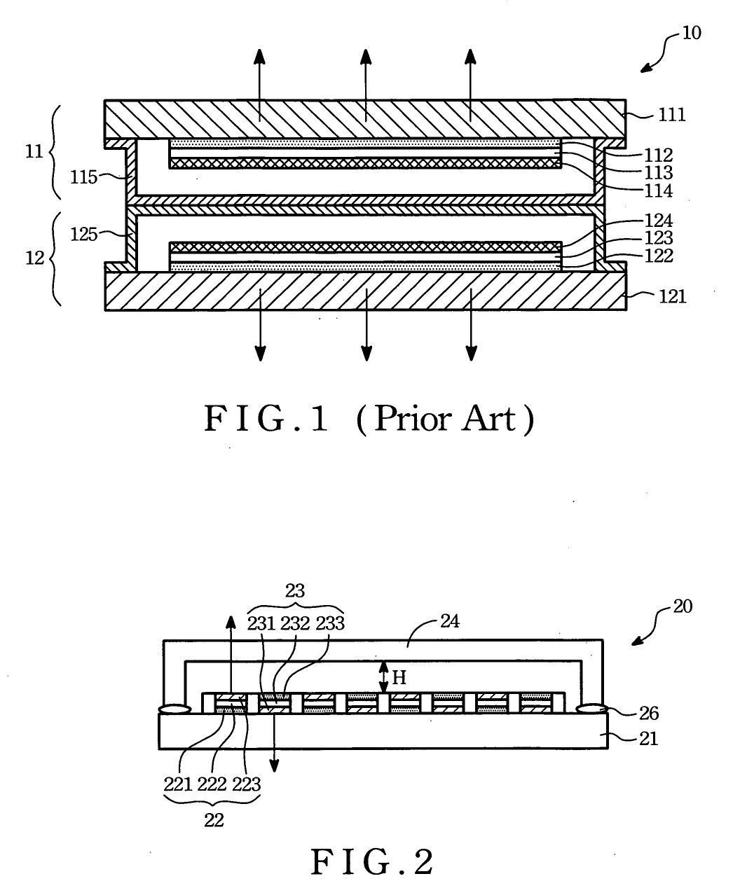

### DESCRIPTION OF THE PREFERRED EMBODIMENT

FIG.2 is the first embodiment of the present invention. A dual emission display 20 includes a substrate 21, two sort of light emitters 22 and 23 having different light-emitting directions, and a cap 24. In following description, the substrate 21 and the cap 24 can be made of organic or inorganic materials.

As shown, the light emitters 22 and 23 are next to each other, and disposed on the same substrate 21. The substrate 21 can be made of glass or plastic. In this embodiment, the dual emission display 20 is capable of displaying images in upper and lower sides since the light emitter 22 emits upward and the light emitter 23 emits downward. The cap 24 is disposed on the light emitters 22 and 23 to prevent external forces from damaging. And also, the cap 24 should be made of the hard materials with light transmissivity of equal to or more than 30 percent, such as glass, hard plastic etc. An adhesive 26 is used to adhere the cap 24 to the substrate 21. A point worth emphasizing is that, there is a distance H ranging about from 1 to 100 μm between the cap 24 and the light emitters 22 and 23. T distance H prevents particles, which is generated from the fabricating process, from damaging the light emitters 22 and 23.

The light emitter 22 can be a top emission OLED, which includes a non-transparent electrode 221 formed on the substrate 21, an organic emission layer 222 formed on the non-transparent electrode 221, and a transparent electrode 223 formed on the organic emission layer 222. The light emitter 22 can be a bottom emission OLED, which also includes a transparent electrode 231, an organic emission layer 232 and a non-transparent electrode 23. Comparing with the top emission OLED, it is the transparent electrode formed on the substrate in bottom emission OLED.

Above OLEDs can be a polymer organic light emitting diode (Polymer OLED) or a small molecular organic light emitting diode (SMOLED). The non-transparent electrode 221 and 223 can be a reflective electrode or a black electrode, which are made of metal, semiconductor, metal oxide or conductive polymer etc. The transparent electrode 223 and 231 is usually made of ITO or IZO. The organic emission layer 222 and 232 are made of a compound with fluorescence or phosphorescence characteristics.

The transparent electrode and the non-transparent electrode are capable of acting as cathode or anode. The hole or electron passing area is between the electrodes and the emission layer. In the hole passing area, a hole injecting layer (not shown) or a hole transporting layer (not shown) is interposed selectively. In the electron passing area, an electron injecting layer (not shown) or an electron transporting layer (not shown) is interposed selectively.

The electron transporting layer may be made of (8-hydroxyquinolinolato) aluminum (Alq), 1,3,5-Tris (N-phenylbenzimidazol-2-yl)benzene (TPBI), derivatives of anthracene, or derivatives of fluorine, spirofluorine etc., mixed with n-type dopant such as alkali halides, alkaline-earth halides, alkali oxides or metal-carbonate compound etc. to increase electron mobility thereof.

The electron injecting layer may be made of metal compound with work function perfectly adapted to that of the non-transparent electrode, such as alkali halides, alkaline-earth halides, alkali oxides or metal-carbonate compound, or an organic layer mixed with such n-type dopants.

The hole transporting layer may be made of allylamine group material such as N,N-di(naphthalene-1-yl)-N,N-diphenyl-benzidene (NPB). The hole injecting layer may be made of allylamine group material, or phthalocyanine group material such as CuP.

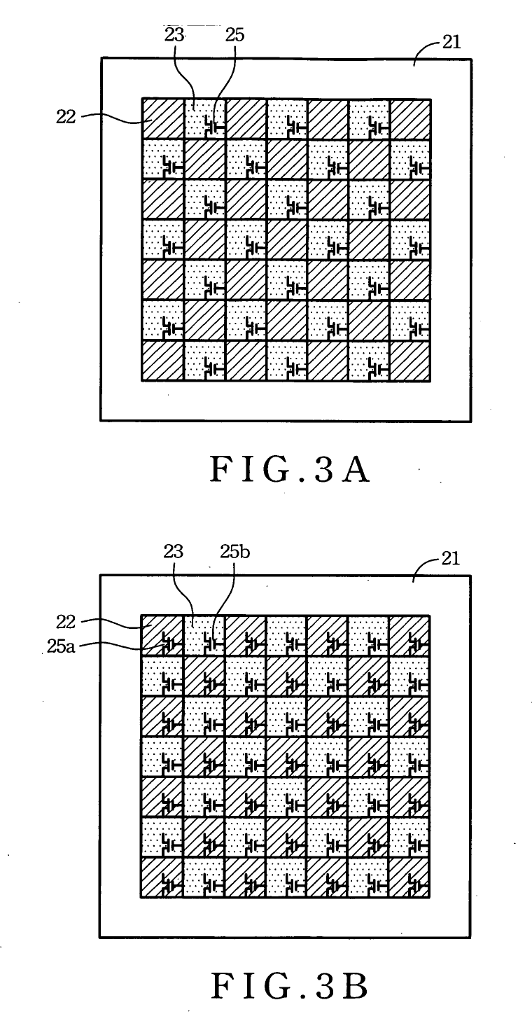

FIG. 3A shows the first type layout diagram of the light emitter according to the first embodiment of the present invention. A plurality of the light emitters 22 and 23 are arranged in chessboard manner or stripe form on the substrate 21. The first and second light emitters 22 and 23 are both driven by the same one driver 25 to display the same image in the upper and lower sides of the dual emission display 20.

FIG. 3B shows the second type layout diagram of the light emitter according to the first embodiment of the present invention. The light emitter 22 is electrically connected to a driver 25a. The light emitter 23 is electrically connected to a driver 25b. The upper and lower side of the dual emission display 20 are controlled independently to display images. The driver 25, 25a and 25b are all not limited to a specific type of thin film transistor. The above layouts are all used in the following embodiments.

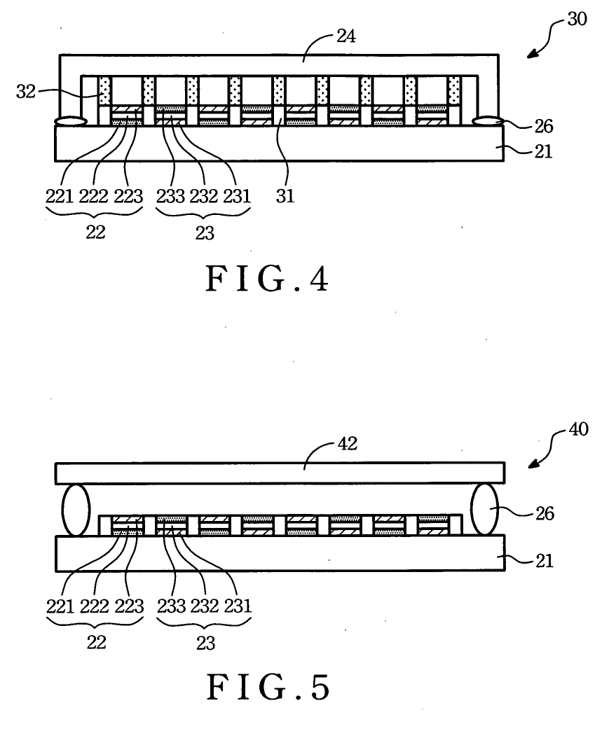

FIG.4 is the second embodiment of the present invention. A supporting layer is formed in the non-upward emitting area of the dual emission display, in order to isolate the substrate from the glass cap. Thus, the supporting layer prevents the cap from damaging the elements mounted on the substrate. In the dual emission display 30, a spacing layer 31 is sandwiched between the upward emitter 22 and the downward emitter 23. A supporting layer 32 is formed on the spacing layer 31 to prevent the cap 24 from caving downward due to external forces. In order to maintain the efficient distance, the supporting layer 32 should have at least 1 to 100 μm height. However, the materials of the supporting layer 32 are not limited to organic or inorganic materials.

As above mentioned, the cap 24 has a body with concave-up inner surface. The adhesive 26 is provided to package the substrate 21 to the low edge of the sidewall of the cap 24. In addition, the cap 24 may be replaced with a flat board, shown in FIG.5.

Refer to FIG. 5, the flat board 42 covers the light emitter 22, 23. The distance between the lower surface of the flat board 42 and the light emitters 22 and 23 is maintained by the adhesive 26, and determined by compositions, volume. It is possible that the supporting strength of the adhesive 26 is insufficient, so the supporting layer 32 is provided to enhance the supporting strength.

Although above description takes active display as an example, the present invention can be applied in a passive display. The characteristics and advantages of the present invention is as follows:
A. reducing the use of integral circuit (IC) or FPCs to save cost;
B. preventing moisture from invading the light emitting portion by packaging the light emitters to the cap with visible light transmissivity of equal to or more than 30 percent; and
C. forming the supporting layer in the non-upward lighting area to isolate the substrate from the cap to prevent damaging the elements mounted on the substrate.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

What is claimed is:

1. A dual emission display, comprising:
a substrate;
a first light emitter disposed on the substrate and having a first light-emitting direction;
a second light emitter disposed on the substrate and adjacent to the first light emitter, the second light emitter having a second light-emitting direction different from the first light emitting direction; and
a cap located on the first emitter and the second emitter, wherein the cap is separated from one of the first emitter and the second emitter by a distance ranging from about 1 μm to 100 μm.

2. The dual emission display of claim 1, further comprising a plurality of the first light emitters and a plurality of the second light emitters arranged in chessboard manner or stripe form.

3. The dual emission display of claim 1, wherein the first light emitter includes:
a non-transparent electrode formed on the substrate;
an organic emission layer formed on the non-transparent electrode; and
a transparent electrode formed on the organic emission layer.

4. The dual emission display of claim 1, wherein the second light emitter includes:
a transparent electrode formed on the substrate;
an organic emission layer formed on the transparent electrode; and
a non-transparent electrode formed on the organic emission layer.

5. The dual emission display of claim 1, wherein the first light emitter comprises a polymer organic light emitting diode.

6. The dual emission display of claim 5, wherein the second light emitter comprises a polymer organic light emitting diode.

7. The dual emission display of claim 1, wherein the cap is made of a material with light transmissivity of equal to or more than 30 percent.

8. The dual emission display of claim 1, wherein the cap has an edge adhered to the substrate.

9. The dual emission display of claim 1, further comprising a driver for driving the first and second light emitters.

10. The dual emission display of claim 1, further comprising a first driver for driving the first light emitter, and a second driver for driving the second light emitter.

11. A dual emission display, comprising:
a substrate;
a first light emitter disposed on the substrate, and having a light-emitting direction upward the substrate;
a second light emitter disposed on the substrate and adjacent to the first light emitter, the second light emitter having a light-emitting direction downward the substrate; and
a cap located on the first emitter and the second emitter; and
a supporting layer, disposed between the cap and the first and second light emitters, for separating the cap from one of the first and second emitters.

12. The dual emission display of claim 11, wherein the supporting layer is about 1 μm to 100 μm in height.

13. The dual emission display of claim 11, including a plurality of the first light emitters and a plurality of the second light emitters arranged in chessboard manner or stripe form.

14. The dual emission display of claim 11, wherein the first light emitter includes:
a non-transparent electrode formed on the substrate;
an organic emission layer formed on the non-transparent electrode; and
a transparent electrode formed on the organic emission layer.

15. The dual emission display of claim 11, wherein the second light emitter includes:
a transparent electrode formed on the substrate;
an organic emission layer formed on the transparent electrode; and
a non-transparent electrode formed on the organic emission layer.

16. The dual emission display of claim 11, wherein the first light emitter comprises a polymer organic light emitting diode.

17. The dual emission display of claim 11, wherein the second light emitter comprises a polymer organic light emitting diode.

18. The dual emission display of claim 1, wherein the cap is made of a material with light transmissivity of equal to or more than 30 percent.

19. The dual emission display of claim 11, wherein the cap has an edge adhered to the substrate.

20. The dual emission display of claim 11, further including a spacing layer interposed between the first and second light emitters, wherein the supporting layer is formed on the spacing layer.
